(19) United States
(12) Patent Application Publication
(10) Pub. No.: US 2026/0369320 A1
(43) Pub. Date: Nov. 19, 2026

(54) RESISTIVE RAM ARRAY WITH SHIELD VOLTAGE-BASED CONTROL OF UNSELECTED COLUMNS

(71) Applicant: SEMICONDUCTOR COMPONENTS INDUSTRIES, LLC, Scottsdale, AZ (US)

(72) Inventor: Thierry YAO, Portland, OR (US)

(73) Assignee: SEMICONDUCTOR COMPONENTS INDUSTRIES, LLC, Scottsdale, AZ (US)

(21) Appl. No.: 19/675,400

(22) Filed: May 12, 2026

Related U.S. Application Data
(60) Provisional application No. 63/807,061, filed on May 16, 2025.

(51) Int. Cl. G11C 13/00

(52) U.S. Cl. CPC G11C 13/0069; G11C 13/0026; G11C 13/0038

(57) ABSTRACT

A method for controlling a resistive random access memory (ReRAM) array includes, during a RESET operation while operating the ReRAM array in a high-resistance state, generating a write command using a processor of a memory control circuit. In response to the write command, the method includes switching a selected column of the ReRAM array from the high-resistance state to a low-resistance state via the memory control circuit. While switching the selected column of the ReRAM array from the high-resistance state to the low-resistance state, the method further includes applying a first non-zero shield voltage to a sourceline and a bitline of an unselected column of the ReRAM array. The memory control circuit includes at least a processor and the ReRAM array.

### CROSS-REFERENCE TO RELATED APPLICATIONS

The present application claims the benefit of priority to United States Provisional Application No. 63/807,061 filed on May 16, 2025, which is hereby incorporated by reference in its entirety.

### TECHNICAL FIELD

The present disclosure relates to electrical circuit topologies that include one or more resistive random access memory elements.

### BACKGROUND

Modern computer systems use microprocessors and volatile and non-volatile memory devices to support a myriad of programmed functions. Computer memory may include ultra-fast registers within a processor chip, cache memory coupled to the processor chip, and various other memory components in communication with the processor chip, all of which have corresponding structure and functions. For instance, random access memory (RAM), e.g., capacitor-based double data rate synchronous dynamic RAM (DDR SDRAM), and read-only memory (ROM) such as magnetic memory/hard disk drives (HDDs), are common examples of volatile and non-volatile memory, respectively. Additionally, an emerging memory technology referred to in the art as resistive RAM (ReRAM) provides an alternative non-volatile memory device that is generally faster and more energy efficient than conventional/volatile RAM devices.

In contrast to operation of volatile RAM which stores an electrical charge, a ReRAM array stores binary data via a voltage-induced change in resistance. In a typical ReRAM array, a switching resistor is driven by a corresponding access transistor, with the ReRAM array including a pair of metal electrodes separated by a dielectric layer, e.g., titanium oxide. During a SET operation, which places a memory cell of the ReRAM array into a defined state (e.g., a binary value of 1), a voltage is applied across the electrodes to create a strong electric field across the dielectric layer. This in turn creates an atomic-level, low-resistance conductive pathway (“filament”) through the dielectric layer. An electric current is permitted to flow between the electrodes across the filament. To perform a RESET operation and return the ReRAM array to a high-resistance state, the polarity of the applied voltage is reversed. Therefore, unlike traditional volatile RAM, a low-resistance SET path and a high-resistance RESET path are controllable in a ReRAM array, with the resistance state persisting even in the absence of power to the array.

### SUMMARY

Shield voltage-based memory control solutions are disclosed herein that address certain shortfalls commonly associated with resistive random access memory (ReRAM) arrays.

In particular, a method for controlling a ReRAM array includes, during a RESET operation while operating the ReRAM array in a high-resistance state, the act of generating a write command using a processor of a memory control circuit. In response to the write command, the method includes switching a selected column of the ReRAM array from the high-resistance state to a low-resistance state, with this transition occurring via the memory control circuit. While switching the selected column from the high-resistance state to the low-resistance state, the method further includes applying a first non-zero shield voltage to a sourceline and a bitline of an unselected column of the ReRAM array.

During a SET operation while in the low-resistance state of the ReRAM array, the method may include generating a subsequent write command via the processor of the memory control circuit. Then, in response to the subsequent write command, the memory control circuit switches the selected column of the ReRAM array from the low-resistance state to the high-resistance state. While switching the selected column to the high-resistance state, the method further includes applying a second positive non-zero shield voltage to the sourceline and the bitline of the unselected column of the ReRAM array.

In different implementations, applying the second positive non-zero shield voltage may include applying voltage that is the same as or different than the first positive non-zero shield voltage.

The method may entail controlling the ReRAM array as a bipolar or a unipolar ReRAM array.

In the various non-limiting embodiments, applying the positive non-zero shield voltage may include applying a voltage of about 1 volt (V) to about 2V, e.g., about 1.2V.

During a simultaneous SET and RESET operation, the method may entail switching one or more cells of the selected column from the high-resistance state to the low-resistance state, doing so via the memory control circuit. In such an embodiment, the method may include simultaneously switching one or more cells of the selected column from the low-resistance state to the high-resistance state, via the memory control circuit, during the simultaneous SET and RESET operation, and then applying the positive non-zero shield voltage to the sourceline and the bitline of one or more cells of an unselected column of the ReRAM array for a duration of the simultaneous SET and RESET operation.

Embodiments of the memory control circuit are also disclosed herein. A representative embodiment of the memory control circuit includes a ReRAM array and a processor in communication therewith. The processor is configured to generate a write command while the ReRAM array operates in a high-resistance state. In response to the write command, the processor switches a selected column of the ReRAM array from the high-resistance state to a low-resistance state. While switching the selected column of the ReRAM array from the high-resistance state to the low-resistance state, the memory control circuit applies a first non-zero shield voltage to a sourceline and a bitline of an unselected column of the ReRAM array.

Another aspect of the disclosure is a method for controlling a ReRAM array that, in a non-limiting implementation, includes generating a write command using a processor of a memory control circuit during a RESET operation. This action occurs while operating the ReRAM array in a high-resistance state. In response to the write command, the method includes switching a selected column of the ReRAM array from the high-resistance state to a low-resistance state via the memory control circuit. Then, while switching the selected column of the ReRAM array from the high-resistance state to the low-resistance state, the method includes applying a first non-zero shield voltage to a sourceline and a bitline of an unselected column of the ReRAM array.

Subsequent to the RESET operation, the method in one or more embodiments includes performing a SET operation while in the low-resistance state by generating a subsequent write command via the processor of the memory control circuit. In response to the subsequent write command, the method includes switching the selected column of the ReRAM array from the low-resistance state to the high-resistance state via the memory control circuit. While switching the selected column of the ReRAM array from the low-resistance state to the high-resistance state, the method includes applying a second positive non-zero shield voltage to the sourceline and the bitline of the unselected column of the ReRAM array, including applying a voltage of about 1V to about 1.5V.

The above summary is not intended to represent every embodiment or aspect of the present disclosure. Rather, the foregoing summary exemplifies certain novel aspects and features as set forth herein. The above noted and other features and advantages of the present disclosure will be readily apparent from the following detailed description of representative embodiments and modes for carrying out the present disclosure when taken in connection with the accompanying drawings and the appended claims.

### BRIEF DESCRIPTION OF THE DRAWINGS

The drawings described herein are for illustrative purposes only, are schematic in nature, and are intended to be exemplary rather than to limit the scope of the disclosure.

FIG. 1 illustrates an example resistive random access memory (ReRAM)-based memory circuit constructed and controlled in accordance with the disclosure.

FIGS. 2A and 2B are schematic illustrations of respective RESET and SET bias conditions for an example ReRAM array usable as part of the memory circuit shown in FIG. 1.

FIG. 3 is a schematic illustration of simultaneous SET and RESET bias conditions for another example ReRAM array for use in the memory circuit of FIG. 1.

FIG. 4 is a flow chart describing an example embodiment of a method for using the ReRAM array of FIGS. 2A, 2B, and 3.

FIGS. 5 and 6 are state tables describing bipolar and unipolar embodiments of a ReRAM array, respectively.

FIG. 7 is a table of representative values usable in one or more embodiments of the memory circuit illustrated in FIG. 1.

The present disclosure may be modified or embodied in alternative forms, with representative embodiments shown in the drawings and described in detail below. Inventive aspects of the present disclosure are not limited to the disclosed embodiments. Rather, the present disclosure is intended to cover alternatives falling within the scope of the disclosure as defined by the appended claims.

### DETAILED DESCRIPTION

The components of the embodiments described and illustrated herein may be arranged and designed in a variety of different configurations. Thus, the following detailed description is not intended to limit the scope of the disclosure as claimed, but is instead representative of possible embodiments thereof. In addition, while numerous specific details are set forth in the following description in order to provide a thorough understanding of the embodiments disclosed herein, some embodiments can be practiced without some of these details. Moreover, for the purpose of clarity, certain technical material that is understood in the related art has not been described in detail in order to avoid unnecessarily obscuring the disclosure.

For purposes of convenience and clarity only, directional terms such as top, bottom, left, right, up, over, above, below, beneath, rear, and front, may be used with respect to the drawings. These and similar directional terms are not to be construed to limit the scope of the disclosure. Furthermore, the disclosure, as illustrated and described herein, may be practiced in the absence of an element that is not specifically disclosed herein. The use of ordinals such as first, second and third does not necessarily imply a ranked sense of order, but may only distinguish between multiple instances of an act or structure.

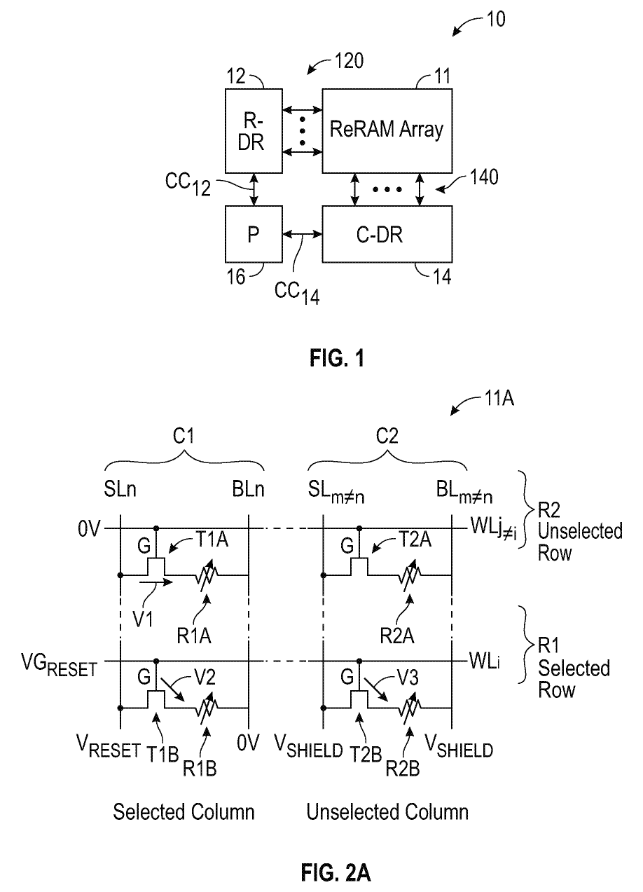

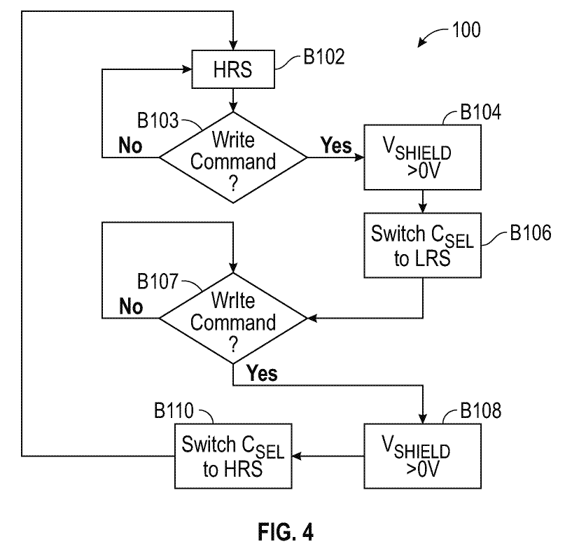

With reference to the drawings, wherein like reference numbers refer to the same or similar components throughout the several views, an example resistive random-access memory (ReRAM) memory control circuit 10 is shown in FIG. 1. The memory control circuit 10 includes a ReRAM array 11 and peripheral circuitry collectively operable for selecting and operating on specific memory cells of the ReRAM array 11. The ReRAM array 11 is controlled in accordance with a control method 100, an example embodiment of which is described below with reference to FIG. 4.

Use of the method 100 for the real-time control of any of the example embodiments of the ReRAM array 11 described herein uses a positive shield voltage technique that reduces gate voltage stress and reduces the required size of the ReRAM array 11. That is, reduced stress from the shield voltage used herein increases reliability and optimization of the access transistor, such as increasing its gate drive voltage to reduce its width for a smaller footprint and/or to increases its threshold voltage for lower drain leakage at high temperatures. As appreciated in the art, lower leakage is a crucial design consideration in automotive memory and a myriad of other applications.

Peripheral circuity used to control state transitions and overall operation of the ReRAM array 11 of FIG. 1 includes a row driver (R-DR) 12, a column driver (C-DR) 14, and one or more processors (P) 16. The processor 16 communicates with the row driver 12 and column driver via digital signal pathways 120 and 140, respectively. Collectively, the peripheral circuitry is responsible for activated a row of the ReRAM array 11, selecting specific memory cells/bit cells within the selected row, and thereafter reading or writing data to the cells based on the commanded operation.

In particular, the row driver 12 acts on a wordline-side of the ReRAM array 11, with the row driver 12 being operable for decoding incoming row addresses CC₁₂ from the processor 16. The processor 16 also activates the wordline for every cell in the processor-selected row via a wordline signal CC₁₄.

The column driver 14 of FIG. 1 operates in a similar manner on a bitline-side of the ReRAM array 11, doing so in response to column address commands CC₁₄ from the processor 16 to address individual cells within the activated/selected row. The column driver 14 ultimately controls the particularbitlines that are electrically connected to the processor 16 at any given time based on a present READ or WRITE operation, typically using pass transistors controlled by a column address decoder, as appreciated in the art.

The processor 16, which sits between the column driver 14 and a data bus (not shown), may also include sense amplifiers and other internal components that collectively detect minute current differences between a high-resistance state and a low-resistance state of selected ReRAM cells, and that convert this information into a clean digital bit. During a WRITE operation, for example, the processor 16 drives voltage (or current) pulses through the selected cells to either set the cells to the low-resistance state in a SET operation, or to reset the cells to the high-resistance state in a RESET operation. Thus, the row driver 12 activates a row, the column driver 14 narrows the selection to specific cells, and the processor 16 reads or writes the data. This coordinated sequence repeats for every memory access.

As appreciated in the art, a ReRAM array such as the example ReRAM array 11 illustrated in FIG. 1 includes three signal lines: the above-noted bitline and wordline, abbreviated herein as BL and WL, respectively, and a sourceline (SL) that connects to a source terminal of an associated access transistor. The bitline is used to apply a READ or WRITE voltage. In the ReRAM array 11, each column shares a single bitline, and therefore a bitline BLₙ services every cell in nominal column n, and so forth. The wordline for a row selection connects to a gate of an associated access transistor, with assertion of a wordline turning on every access transistor in a selected row, thereby connecting their respective switching elements to their sourceline(s).

During a READ operation, the sourceline is typically held at ground. During a WRITE operation, the polarity between the bitline and sourceline determines whether a SET or a RESET operation is taking place. Therefore, the wordline selects a row, with the bitline and sourceline together applying a stimulus across a selected cell, and the above-noted access transistor ensuring that only the bitcells in the selected row see the voltage (or current). Access transistors in unselected rows of the ReRAM array 11 are typically kept in an OFF (non-conducting) state for better electrical isolation regardless of the resistance state.

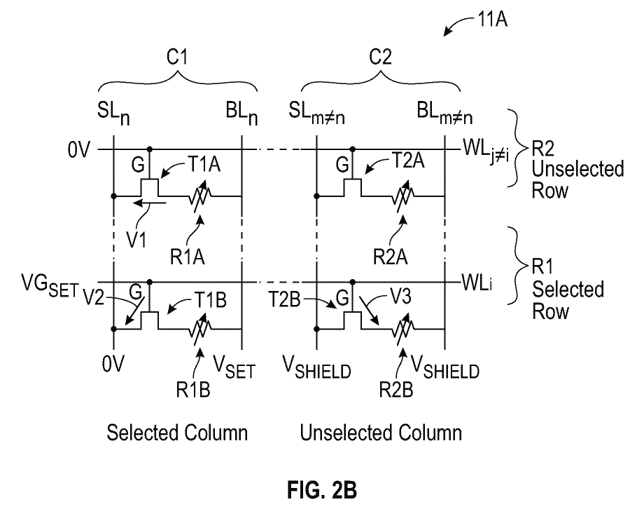

ReRAM RESET: Referring now to FIG. 2A, an example ReRAM array 11A is shown during a RESET operation in which the ReRAM array 11A is transitioned from a low-resistance state to a state of high-resistance. For simplicity, cells are shown in a selected column C1 and an unselected column C2, and in a selected row R1 and an unselected row R2. In the selected column C1, the ReRAM array 11A includes respective first and second access transistors T1A and T1B. The selected column C1 also includes respective first and second resistive elements R1A and R1B, i.e., variable resistors having a selectable resistance, as appreciated in the art.

The access transistors T1A and T1B, and other access transistors as set forth below, can be embodied as, e.g., field effect transistors (FETs) of different constructions, for instance planar, metal gate, finfet, nanoribbon, etc. Such components have three main terminals: gate, drain, and source. A fourth terminal referred to as the body may be electrically tied to the source, the silicon substrate (ground), or to an isolated body diffusion that the transistor may be fabricated on. The resistive elements R1A and R1B, as well as others, can be any resistor having an electrically switchable or variable resistance between a nominal high and nominal low value, and which conserves the high/low value between operations. As appreciated, each bitcell of the ReRAM array 11 is formed by electrically tying one of two electrodes of a given resistive element/switching resistor to one of two diffusions (drain or source) of the access transistor. The other electrode of the switching resistor forms a first shared column terminal/electrode line. The other diffusion terminal forms a second shared column terminal/diffusion line. The gate terminal of the access transistor forms a shared row terminal, i.e., a wordline.

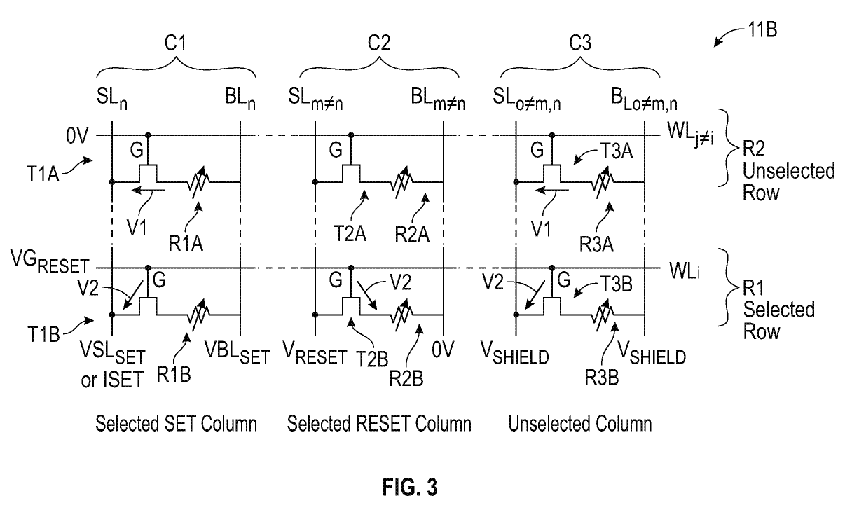

The ReRAM array 11A in the example embodiment of FIG. 2A has respective complementary first and second bitlines BLₙ and BL_{m ≠ n}, with the first bitline BLₙ being in the selected column C1. The ReRAM array 11A also includes respective first and second sourcelines SLₙ and SL_{m ≠ n}, with the sourceline SLₙ being in the selected column C1 in the FIG. 1 embodiment. Respective first and second word lines WLᵢ and WL_{j≠i}form a crossbar configuration with the first and second bitlines BLₙ and BL_{m ≠ n}and the first and second sourcelines SLₙ and SL_{m ≠ n}. The ReRAM array 11A may be of any application-specific size, as indicated by “- - -” in FIGS. 2A, 2B, and 3.

In the illustrated embodiment of the array 11A, the bitline BLₙ is connected to the resistive elements R1A and R1B, and is used to apply a voltage/current during WRITE and READ operations of the ReRAM array 11A. The wordline WL_{j≠1}is connected to a gate terminal G of the first access transistor T1A, such that activation via the gate terminal G turns ON the first access transistor T1A to allow an electric current to flow through the resistive element R1A. A similar process occurs during a SET operation with the wordline WLᵢ and a gate terminal G of the second access transistor T1B, i.e., activation via the gate terminal G turns ON the second access transistor T1B to allow an electric current to flow through the resistive element R1B.

The source line SLₙ in FIG. 2A is also connected to the first access transistor T1A (or to its drain, depending on convention) to provide a return path for the above-noted electric current, and to control a polarity of a voltage across the resistive element R1A. Switching between SET and RESET states involves applying a voltage of opposite polarity across the resistive element R1A. By controlling relative voltages on the bitlines and the sourcelines, e.g., BLₙand SLₙ, and using the write line WL_{j≠ i}to turn ON the access transistor T1A, the processor 16 (FIG. 1) is able to reverse a current direction through the ReRAM array 11A.

Referring briefly again to FIG. 1, sense amplifier circuitry (not shown) of the processor 16 is coupled to the column driver 14 and configured to detect a resistance state of a selected one of the resistive elements R1A, R1B, R2A, and R2B of FIG. 2A during a READ operation. This occurs by sensing a current or voltage differential indicative of a high-resistance state or a low-resistance state. Additionally, a shield bias function of the processor 16 is configured herein to apply a predetermined shield voltage V_{SHIELD} to the bitlines and sourcelines of the unselected column C2 of FIG. 2A, such that a zero voltage differential is maintained across the resistive elements of any unselected cells. Use of a non-zero shield voltage V_{SHIELD} as set forth herein mitigates WRITE disturbances, with the particular positive and non-zero shield voltage V_{SHIELD}, e.g., 1-2 volts (V), selected to reduce gate-to-source voltage stress on the access transistors T2A, T2B of the unselected column C2, thereby mitigating bias temperature instability degradation.

Referring once again to FIG. 2A, the ReRAM array 11A has a circuit topology that is arranged in the rows R1 and R2 and columns C1 and C2. Columns that are not accessed during a given READ or WRITE operation of the ReRAM array 11A are referred to as “unselected columns”, i.e., column C2 in the example of FIG. 2A. Thus, “selected columns” encompass the particular bitline-sourceline pair for an activated wordline, with column C1 being the selected column in this example RESET operation. Also shown in FIG. 2A are VG_{RESET} and V_{RESET}, which as appreciated in the art are applied voltages from a low-voltage power supply (not shown) that respectively control the gate G of the access transistors T1B and T2B (and thus the energy needed to trigger RESET switching), and a driving voltage on the sourcelines SLₙ and SL_{m≠n}. Together, VG_{RESET} and V_{RESET} define the current-voltage operating point of the example RESET operation.

When addressing the ReRAM array 11A during a READ or WRITE operation, therefore, a row is first selected by activating the wordline. Selecting row R1, for instance, requires activating the wordline WLᵢ. Selecting a column occurs by driving an appropriate voltage on the corresponding bitline-sourceline pair, e.g., BLₙ and SLₙ of selected column C1. The other column in the simplified embodiment of FIG. 2A, i.e., column C2, also has its access transistor T2B turned ON by the shared wordline, or WLᵢ in this example.

In a RESET operation in the non-limiting embodiment of FIG. 1, the present approach as disclosed herein shields the access transistors of unselected columns from a high RESET gate voltage. In FIG. 2A, this entails shielding the access transistors T2A and T2B of unselected column C2. This is accomplished using a predetermined non-zero shield voltage V_{SHIELD}, i.e., in (non-trivial) excess of 0V, for instance about 1.2V in a possible embodiment. That is, rather than grounding the bitline BL_{m≠n}and sourceline SL_{m≠n}of the unselected column C2, a relatively high, i.e., non-trivial/non-zero shielding voltage is applied to the bitline BL_{m≠n}and sourceline SL_{m≠n}. As a result, gate stress/bias temperature instability (BTI) is reduced across the access transistor T2B during the RESET operation, thus providing sufficient margins for increasing the RESET gate voltage. This action in turn enables reduction of the gate width of the access transistors T2A and T2B, i.e., the physical width of the gate electrode of the accessor transistors T2A and T2B as measured perpendicular to a direction of current flow between their respective source and drain.

As appreciated, all transistors in the ReRAM array are of the same nature and dimensions, and therefore gains in gate voltage margin may be used to increase VGRESET and narrow the gates, i.e., reduce the size of the various access transistors. Also as appreciated, all bitcells in the ReRAM arrays described herein are identical, i.e., are of the exact same type and dimensions. The access transistors T1A, T2A, T2A, and T2B are of the same brand, model, and size, and are only labeled differently herein for illustrative clarity. Thus, statements herein relative to modifying characteristics of an access transistor are understood to apply uniformly to all access transistors used in a given topology, i.e., individual access transistors within the ReRAM arrays described herein are not treated differently.

In FIG. 2A, a representative illustrative scenario may be considered in which for an example VG_{RESET} value of 2.7V, an example non-zero shield voltage V_{SHIELD} of 1.2V is applied to the bitline BL_{m≠n} and sourceline SL_{m≠n} of the unselected column C2. Application of the higher V_{SHIELD} value of 1.2V in this non-limiting scenario would result in a voltage V3 across the access transistor T2B in the unselected column C2, with V3 = VG_{RESET} - V_{SHIELD} = 2.7V – 1.2V = 1.5V in this example. A voltage V2 across the access transistor T1B of the selected column C1 would be about 1.7V, with a voltage V1 = 2V across the access transistor T1A of selected column C1 in this illustrative embodiment.

In a current state-of-the art approach that grounds the sourcelines and bitlines of any unselected columns, i.e., one which applies a voltage of 0V instead of the proposed non-zero voltage of the present approach, the voltage V3 across the access transistor T2B in unselected column C2 would be significantly higher, i.e., approximately equal to VG_{RESET}, or about 2.5V in this example versus 1.5V achieved via the present approach. Use of the non-zero shield voltage therefore allows for a higher current to be driven across the resistive element R1B in the selected row R1 of the selected column C1. Alternatively, one may use smaller access transistors to benefit in that manner.

ReRAM SET: Referring now to FIG. 2B, the ReRAM array 11A is shown during a SET operation. The operation of FIG. 2A is reversed, with different values for voltages V2 and V3, and a different polarity for voltage V1 relative to the RESET operation of FIG. 2A. Here, V_{SHIELD} = 1.2V in keeping with the example of FIG. 2A, with V_{SET} = 2V on the bitline BLn, and with a zero voltage/0V on the sourceline SLn of the selected column C1.

During SET, the voltage drop V3 across the access transistor T2B of unselected column C2 is equal to V3 = VG_{SET} – V_{SHIELD} = 1.5V – 1.2V = 0.3V. Relative to conventional approaches grounding the sourceline and bitline of the unselected column C2, which would result in a V3 value of 1.5V in this non-limiting example, the use of the positive non-zero shield voltage V_{SHIELD} effectively shields the access transistors T2A and T2B in the unselected column C2 from VG_{SET} value, thereby lowering gate stress below rated values of the two access transistors T2A and T2B.

SIMULTANEOUS SET-RESET: Referring now to FIG. 3, an alternative construction of a ReRAM array 11B is illustrated in which SET and RESET operations are operated simultaneously. As understood in the art, SET and RESET columns are selected for SET and RESET operations, respectively. Only one row in each type of column is selected for operation. For example, only high-resistance (high-R) bitcells are selected for a SET operation, while only low-R bitcells are selected for a RESET operation, if need be. If a word LHHL (L=Low-R, H=Hi R) needs to be rewritten as LLHH, for instance, the write operation would be USUR (U=Unsel, S=Set, R= Reset). In this case, SET and RESET are performed simultaneously. This action may be performed in two steps: (1) RESET with UUUR, and (2) RESET with USUU.

In this configuration, C1 is a selected SET column, C2 is a selected RESET column, and C3 is an unselected column. As column C1 is selected for a SET operation, the memory control circuit 10 switches one or more targeted cells in column C1 from a high-resistance state to a low-resistance state. Switching also involves simultaneously switching one or more cells of the selected RESET column C2 from the low-resistance state to the high-resistance state, likewise via the memory control circuit 10, during the simultaneous SET and RESET operation. At the same time, the positive non-zero shield voltage is applied to the sourceline and the bitline of one or more cells of the unselected column C3.

For selected SET column C1 in this example, VSL_{SET} is the set voltage applied to the sourceline SLn, e.g., 1V in an example case. VBL_{SET} is the set voltage applied to the bitline BLn of the selected column C1, e.g., 3V, which is a higher voltage supplying an electric potential that pushes an electric current through the resistive element R1B. A voltage drop V2 across the cell during a SET operation is represented as VBL_{SET} - VSL_{SET}, and is modulated by the access transistor T1B. Unselected column C3, with its access transistors T3A and T3B, and with its resistive elements R3A and R3B, is controlled as described above with reference to FIGS. 2A. Here, the voltage V1 across the access transistor T3A is the same as the voltage V1 across the access transistor T1A, e.g., 2V, while the voltage V2 is the same in columns C1 and C3 as shown. Voltage V2 is also present as a drop across the access transistor T2B of column C2, albeit with reverse polarity.

Referring to the method 100 of FIG. 4, a process for controlling the ReRAM array 11 of FIG. 1 (and its embodiments of FIGS. 2A, 2B, and 3) during a state transition of the ReRAM array 11. The method 100 can be executed by the processor 16 of the memory control circuit 10 of FIG. 1 during operation of the ReRAM array 11. For illustrative clarity, the method 100 is illustrated as discrete code segments or logic blocks executable by the processor 16 in the particular sequence described below.

Beginning with block B102 (“HRS”), the ReRAM array 11 starts out in an example in the high-resistance state (HRS) in a SET operation. The method 100 proceeds to block B103 while the SET operation is ongoing.

At block B103 (“Write Command ?”), while in the high-resistance state of the ReRAM array 11, the method 100 includes generating a write command via the memory control circuit 10. That is, the row driver 12 may receive a write command from the processor 16 of FIG. 1 to trigger a transition to the low-resistance state from the high-resistance state, thus initiating a RESET operation in this example.

Block B103 may entail decoding the write command, e.g., via a bitline driver (not shown), and thereafter applying an appropriate voltage or current pulse via the bitline driver to a selected bitline in a selected row of the ReRAM array 11. Thus, in response to the write command, the method 100 includes switching a selected column of the ReRAM array 11 from the high-resistance state to the low-resistance state via the memory control circuit 10. The method 100 thereafter proceeds to block B104 when the write command has been received, and repeats blocks B102 and B103 in a loop in the alternative.

At block B104 (“V_{SHIELD} > 0V”), while switching the selected column of the ReRAM array 11 from the high-resistance state to the low-resistance state, the method 100 includes applying a positive, non-zero shield voltage to a sourceline and a bitline of an unselected column of the ReRAM array 11, e.g., column C2 of FIGS. 2A and 2B and column C3 of FIG. 3. In the non-limiting examples set forth above, for instance, a shield voltage of about 1-2V may be applied, or about 1-1.5V, e.g., 1.2V for an example VG_{SET} value of 1.5 V. Block B104 is thus used in lieu of prior art approaches that ground the sourceline and bitline of unselected columns. The method 100 then proceeds to block B106.

Block B106 (“Switch C_{SEL} to LRS”) includes switching the selected column of the ReRAM array 11 from the high-resistance state to the low-resistance state while applying the positive, non-zero shield voltage V_{SHIELD} of block B104 to a sourceline and a bitline of the unselected column of the ReRAM array 11. The method 100 thereafter proceeds to block B107.

Block B107 (“Write Command ?”) is analogous to above-described block B103. At block B107, while operating in the low-resistance state of the ReRAM array 11, the method 100 includes generating a subsequent write command via the processor 16 of the memory control circuit 10 illustrated in FIG. 1. Such a command triggers a RESET operation, as appreciated in the art. Block B107 proceeds in a loop unit includes, in response to the subsequent write command, the method 100 includes switching a selected column of the ReRAM array 11 from the high-resistance state to the low-resistance state via the memory circuit 10. The method 100 thereafter proceeds to block B108 when the write command has been received, and repeats blocks B102 and B103 in a loop in the alternative.

At block B108 (“V_{SHIELD} > 0V), in response to the subsequent write command noted above, switching the selected column of the ReRAM array 11 from the low-resistance state to the high-resistance state occurs via the memory control circuit 10 shown in FIG. 1. While switching the selected column of the ReRAM array 11 from the low-resistance state to the high-resistance state, the method 100 includes applying a positive, non-zero shield voltage to the sourceline and the bit line of the unselected column of the ReRAM array 11. The shield voltage V_{SHIELD} may the same as or different than the shield voltage applied at block B104 in different embodiments. In the non-limiting FIG. 2B RESET example described above, for instance, a shield voltage of about 1-2V may be applied, for instance 1.2V for an example VG_{RESET} value of 2.5 V. The method 100 then proceeds to block B110.

Block B110 (“Switch C_{SEL} to HRS”) includes switching the selected column of the ReRAM array 11 of FIG. 1 from the low-resistance state to the HRS while applying the positive, non-zero shield voltage V_{SHIELD} of block B108 to the sourceline and bitline of the unselected column of the ReRAM array 11. The method 100 thereafter returns to block B102.

The present teachings may be applied to bipolar and unipolar constructions of the ReRAM array 11. As appreciated in the art, bipolar constructions have distinct performance advantages, including but not limited to improved controllability and endurance. SET and RESET operations of a ReRAM array such as the example ReRAM array 11 of FIG. 1 require opposite voltage polarities for proper ion migration when forming and deconstructing the above-described conductive filament. In contrast, a simpler unipolar ReRAM array uses the same voltage polarity, instead varying the amplitude and duration of the control voltage or current pulse. Bipolar embodiments thus require relatively complex driver circuitry, while a unipolar construction tends to be simpler to drive, but with reduced switching performance and overall endurance. However, both configurations benefit from the shield voltage technique implemented via the above-described method 100.

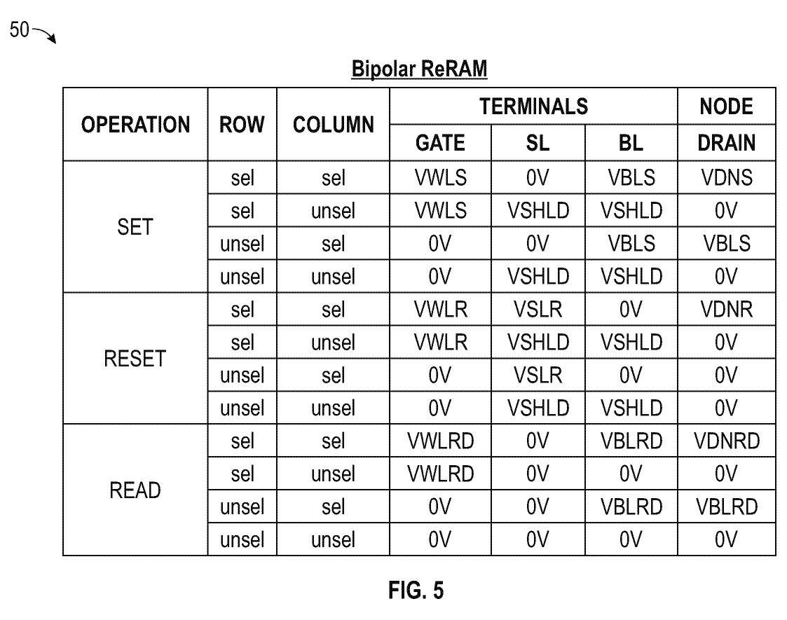

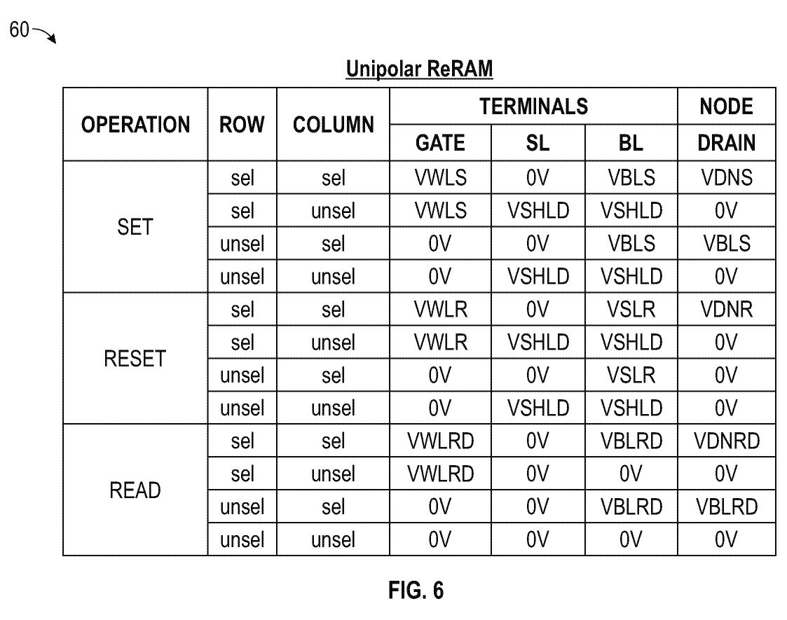

Referring briefly to FIGS. 5 and 6, tables 50 and 60 are shown for a bipolar and unipolar construction of the ReRAM array 11 of FIG. 1, respectively. Both tables 50 and 60 illustrate parameters for selected (sel) and unselected (unsel) rows and columns for SET, RESET, and READ operations. Tables 50 and 60 also illustrate parameters for the access transistor gate, sourceline (SL), and bitline (BL) terminals, along with the drain of the access transistor.

In FIGS. 5 and 6, the parameters include the shield voltage (VSHLD), 0V, along with set wordline voltage (VWLS), set bitline voltage (VBLS), reset wordline voltage (VWLR), reset sourceline voltage (VSLR), read wordline voltage (VWLRD), read bitline voltage (VBLRD), and drain node voltage during set (VDNS), drain node voltage during read (VDNRD), and drain node voltage during reset (VDNR). In both of tables 50 and 60, therefore, the non-zero shield voltage VSHLD > 0, e.g., 1-2V or 1.2V in the above examples, is applied to sourceline (SL) and bitline (BL) of the unselected column (unsel) during SET and RESET operations. The non-zero shield voltage is not applied during READ, with 0V instead applied to the sourceline (SL) and bitline (BL) during READ operations.

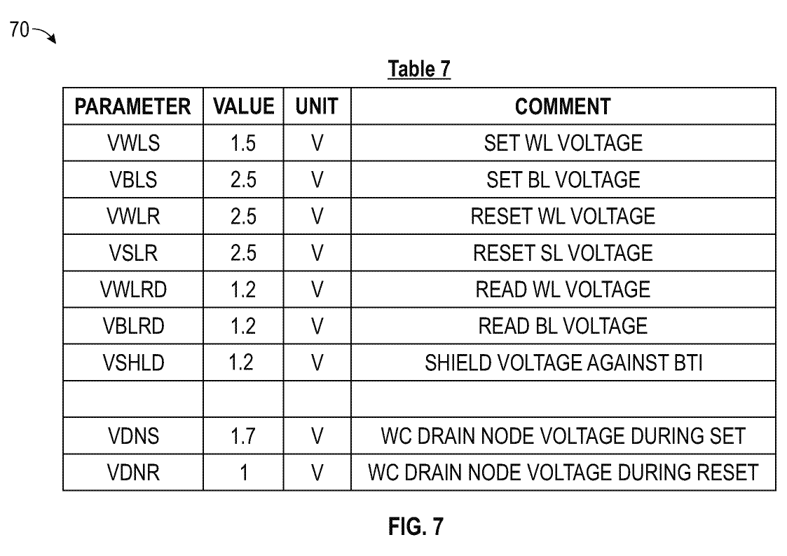

Table 70 of FIG. 7 illustrates non-limiting example values for the above-noted parameters. In this example, VSHLD is 1.2V when the highest voltage control value is 2.5V, i.e., for VBLS, VWLR, and VSLR. Higher or lower shield voltages may be used in other applications to turn performance based on the values of the other parameters and the particular construction of the ReRAM array 11. Therefore, the values of FIG. 7 are representative of just one possible implementation within the scope of the disclosure.

In accordance with the above teachings, the solutions provided herein may help minimize the required size of access transistors by reducing the size of bitcells within a ReRAM array, e.g., the example ReRAM array 11 of FIG. 1 and its embodiments 11A and 11B of FIGS. 2A, 2B, and 3. Reducing silicon area has the advantage of increasing memory density by reducing gate voltage stress significantly enough to allow a larger gate overdrive current. These and other attendant benefits will be readily appreciated by those of ordinary skill in the art in view of the foregoing disclosure.

The numerical values of parameters (e.g., of quantities or conditions) in this specification, including the appended claims, are to be understood as being modified in each respective instance by the term “about” whether or not “about” actually appears before the numerical value. “About” indicates that the stated numerical value allows some slight imprecision (with some approach to exactness in the value; about or reasonably close to the value; nearly, e.g., within ±10% of the stated value). If the imprecision provided by “about” is not otherwise understood in the art with this ordinary meaning, then “about” as used herein indicates at least variations that may arise from ordinary methods of measuring and using such parameters. In addition, disclosure of ranges includes disclosure of each value and further divided ranges within the entire range. Each value within a range and the endpoints of a range are hereby disclosed as separate embodiments.

The term "signal" refers herein to a physically discernible indicator that conveys information, and may be a suitable waveform (e.g., electrical, optical, magnetic, mechanical or electromagnetic), such as DC, AC, sinusoidal-wave, triangular-wave, square-wave, vibration, and the like, that is capable of traveling through a medium.

The detailed description and the drawings or FIGS. are supportive and descriptive of the disclosure, but the scope of the disclosure is defined solely by the claims. While some of the best modes and other embodiments for carrying out the claimed disclosure have been described in detail, various alternative designs and embodiments exist for practicing the disclosure defined in the appended claims.

Furthermore, the embodiments shown in the drawings, or the characteristics of various embodiments mentioned in the present description are not necessarily to be understood as embodiments independent of each other. Rather, it is possible that each of the characteristics described in one of the examples of an embodiment can be combined with one or a plurality of other desired characteristics from other embodiments, resulting in other embodiments not described in words or by reference to the drawings. Accordingly, such other embodiments fall within the framework of the scope of the appended claims.

What is claimed is:

1. A method for controlling a resistive random access memory (ReRAM) array, the method comprising:
during a RESET operation while operating the ReRAM array in a high-resistance state, generating a write command using a processor of a memory control circuit;
in response to the write command, switching a selected column of the ReRAM array from the high-resistance state to a low-resistance state via the memory control circuit; and
while switching the selected column of the ReRAM array from the high-resistance state to the low-resistance state, applying a first non-zero shield voltage to a sourceline and a bitline of an unselected column of the ReRAM array.

2. The method of claim 1, further comprising:
during a SET operation while in the low-resistance state of the ReRAM array, generating a subsequent write command via the processor of the memory control circuit;
in response to the subsequent write command, switching the selected column of the ReRAM array from the low-resistance state to the high-resistance state via the memory control circuit; and
while switching the selected column of the ReRAM array from the low-resistance state to the high-resistance state, applying a second positive non-zero shield voltage to the sourceline and the bitline of the unselected column of the ReRAM array.

3. The method of claim 2, wherein applying the second positive non-zero shield voltage includes applying voltage that is the same as the first positive non-zero shield voltage.

4. The method of claim 2, wherein applying the second positive non-zero shield voltage includes applying voltage that is different than the first positive non-zero shield voltage.

5. The method of claim 1, further comprising: controlling the ReRAM array as bipolar ReRAM array.

6. The method of claim 1, further comprising: controlling the ReRAM array as a unipolar ReRAM array.

7. The method of claim 1, wherein applying the positive non-zero shield voltage includes applying a voltage of about 1 volt (V) to about 2V.

8. The method of claim 7, wherein applying the positive non-zero shield voltage includes applying a voltage of about 1.2V.

9. The method of claim 1, the method further comprising:
during a simultaneous SET and RESET operation, switching one or more cells of the selected column from the high-resistance state to the low-resistance state, via the memory control circuit;
simultaneously switching one or more cells of the selected column from the low-resistance state to the high-resistance state, via the memory control circuit, during the simultaneous SET and RESET operation; and
applying the positive non-zero shield voltage to the sourceline and the bitline of one or more cells of an unselected column of the ReRAM array, via the memory control circuit, for a duration of the simultaneous SET and RESET operation.

10. A memory control circuit, comprising:
a resistive random access memory (ReRAM) array; and
a processor in communication with the ReRAM array, wherein the processor is configured to:
generate a write command while the ReRAM array operates in a high-resistance state;
in response to the write command, switch a selected column of the ReRAM array from the high-resistance state to a low-resistance state; and
while switching the selected column of the ReRAM array from the high-resistance state to the low-resistance state, apply a first non-zero shield voltage to a sourceline and a bitline of an unselected column of the ReRAM array.

11. The memory control circuit of claim 10, further comprising:
a row driver; and
a column driver, wherein the row driver and the column driver are in communication with the processor as part of the memory control circuit.

12. The memory control circuit of claim 10, wherein the processor is configured to:
generate a subsequent write command while the ReRAM array is in the low-resistance state;
switch the selected column of the ReRAM array from the low-resistance state to the high-resistance state in response to the subsequent write command; and
apply a second positive non-zero shield voltage to the sourceline and the bitline of the unselected column of the ReRAM array while switching the selected column of the ReRAM array from the low-resistance state to the high-resistance state.

13. The memory control circuit of claim 12, wherein the processor is configured to applying the second positive non-zero shield voltage as a voltage that is the same as the first positive non-zero shield voltage.

14. The memory control circuit of claim 12, wherein the processor is configured to applying the second positive non-zero shield voltage as a voltage that is different from the first positive non-zero shield voltage.

15. The memory control circuit of claim 10, wherein the memory control circuit is configured to control the ReRAM array as a bipolar ReRAM array.

16. The memory control circuit of claim 10, wherein the memory control circuit is configured to control the ReRAM array as a unipolar ReRAM array.

17. The memory control circuit of claim 10, wherein the processor is configured to apply the positive non-zero shield voltage as voltage of about 1 volt (V) to about 2V.

18. The memory control circuit of claim 10, wherein the ReRAM array is configured to:
switch one or more cells of a selected SET column from the high-resistance state to the low-resistance state during a simultaneous SET and RESET operation of the ReRAM array;
simultaneously switch one or more cells of the selected RESET column from the low-resistance state to the high-resistance state during the simultaneous SET and RESET operation of the ReRAM array; and
apply the positive non-zero shield voltage to the sourceline and the bitline of one or more cells of an unselected column of the ReRAM array for a duration of the simultaneous SET and RESET of the ReRAM array.

19. A method for controlling a resistive random access memory (ReRAM) array, the method comprising:
during a RESET operation while operating the ReRAM array in a high-resistance state, generating a write command using a processor of a memory control circuit;
in response to the write command, switching a selected column of the ReRAM array from the high-resistance state to a low-resistance state via the memory control circuit;
while switching the selected column of the ReRAM array from the high-resistance state to the low-resistance state, applying a first non-zero shield voltage to a sourceline and a bitline of an unselected column of the ReRAM array;
subsequent to the RESET operation, performing a SET operation while in the low-resistance state by generating a subsequent write command via the processor of the memory control circuit;
in response to the subsequent write command, switching the selected column of the ReRAM array from the low-resistance state to the high-resistance state via the memory control circuit; and
while switching the selected column of the ReRAM array from the low-resistance state to the high-resistance state, applying a second positive non-zero shield voltage to the sourceline and the bitline of the unselected column of the ReRAM array,
including applying a voltage of about 1 volt (V) to about 1.5V.

20. The method of claim 19, the method further comprising:
switching one or more cells of the selected column from the high-resistance state to the low-resistance state, via the memory control circuit, during a simultaneous SET and RESET operation of the ReRAM array;
simultaneously switching one or more cells of the selected column from the low-resistance state to the high-resistance state, via the memory control circuit, during the simultaneous SET and RESET operation of the ReRAM array; and
applying the positive non-zero shield voltage to the sourceline and the bitline of one or more cells of an unselected column of the ReRAM array, via the memory control circuit, for a duration of the simultaneous SET and RESET of the ReRAM array.
